(19) United States
(12) Patent Application Publication
(10) Pub. No.: US 2012/0294458 A1
(43) Pub. Date: Nov. 22, 2012

(54) SEMICONDUCTOR INTEGRATED CIRCUIT OF CAR NAVIGATION SYSTEM AND MULTIMEDIA PROCESSING METHOD APPLIED TO CAR NAVIGATION SYSTEM INTEGRATED WITH FM/AM BROADCAST RECEIVING FUNCTION

(76) Inventor: Lifang Wang, Anhui Province (CN)

(21) Appl. No.: 13/140,017

(22) PCT Filed: May 17, 2011
(86) PCT No.: PCT/CN2011/074140

§ 371 Date: Jun. 16, 2011

(51) Int. Cl. H03G 5/00; H04B 1/16

(52) U.S. Cl. 381/98; 381/119

(57) ABSTRACT

A semiconductor IC includes an analog audio input circuit, a selecting unit, and an audio processing circuit, which maybe a car navigation chip. The analog audio input circuit includes an RF module and at least one analog audio input module, respectively for providing a first analog audio input signal and at least one second analog audio input signal. The RF module includes an FM/AM broadcast receiving function. The selecting unit is coupled to the RF module and analog audio input module, and outputs a target analog audio input signal according to the first and second analog audio input signals. The audio processing circuit is coupled to the selecting unit, and performs an audio signal process upon the target analog audio signal to generate an audio output signal.

### TECHNICAL FIELD

The present disclosure relates to a semiconductor integrated circuit and related multimedia processing method, and more particularly, to a semiconductor integrated circuit and related multimedia processing method applied to a car navigation system integrated with an FM/AM broadcast receiving function.

### BACKGROUND

Recently, a car navigation system has become a basic equipment on a vehicle. Besides, a frequency modulation/amplitude modulation (FM/AM) broadcast receiving function plays an important role in the car navigation system. Typically, one of the current practice is to externally plug in an extra FM/AM radio receiver to the car navigation chip and integrate them on the same PCB board, and discard the FM/AM radio receiver originally disposed in the vehicle. However, the use of the extra FM/AM radio receiver inevitably results in increased production cost and complicated circuit architecture. Another current practice is to adopt the FM/AM radio receiver originally disposed in the vehicle and a car navigation chip without an FM/AM broadcast receiving function, and then use a selector to select or mix the audio input signals outputted from the FM/AM radio receiver originally disposed in the vehicle and the car navigation chip without the FM/AM broadcast receiving function. This, however, may result in higher production cost.

Hence, how to save the production cost and the PCB board area of the car navigation system has become an important topic for designers in this field.

### SUMMARY

It is one of the objectives of the claimed disclosure to provide a semiconductor IC and related multimedia processing method applied to a car navigation system to solve the above-mentioned problems.

According to one aspect of the present disclosure, an exemplary semiconductor IC is provided. The exemplary semiconductor IC includes an analog audio input circuit, a selecting unit, and an audio processing circuit. The analog audio input circuit includes an RF module and at least one analog audio input module. The RF module at least includes a frequency modulation/amplitude modulation (FM/AM) broadcast receiving function and is arranged to provide a first analog audio input signal. The at least one analog audio input module is arranged to provide at least one second analog audio input signal. The selecting unit is coupled to the RF module and the analog audio input module, wherein the selecting unit arranged to output a target analog audio input signal according to the first analog audio input signal and the at least one second analog audio input signal. The audio processing circuit is coupled to the selecting unit, wherein the audio processing circuit arranged to perform an audio signal process upon the target analog audio signal to generate an audio output signal.

According to another aspect of the present disclosure, an exemplary multimedia processing method applied to a car navigation system is provided. The exemplary method includes the following steps: disposing an analog audio input circuit, a selecting unit, and an audio processing circuit in a semiconductor integrated circuit (IC), wherein the analog audio input circuit comprises an RF module and at least one analog audio input module, and the RF module at least comprises a frequency modulation/amplitude modulation (FM/AM) broadcast receiving function; using the RF module to provide a first analog audio input signal, and using the at least one analog audio input module to provide at least one second analog audio input signal; outputting a target analog audio input signal according to the first analog audio input signal and the at least one second analog audio input signal via the selecting unit; performing an audio signal process upon the target analog audio signal to generate an audio output signal via the audio processing circuit.

By integrating the RF module equipped with an RF/AM broadcast receiving function into a car navigation chip, an extra FM/AM radio receiver equipped with the FM/AM broadcast receiving function can be saved. Therefore, not only can the production cost and the PCB board area be saved, but also the circuit architecture of the car navigation chip can be simplified.

These and other objectives of the present disclosure will no doubt become obvious to those of ordinary skill in the art after reading the following detailed description of the preferred embodiment that is illustrated in the various figures and drawings.

### BRIEF DESCRIPTION OF DRAWINGS

FIG. 1 is a block diagram illustrating a semiconductor IC according to a first embodiment of the present disclosure.

FIG. 2 is a block diagram illustrating a semiconductor IC according to a second embodiment of the present disclosure.

FIG. 3 is a block diagram illustrating a semiconductor IC according to a third embodiment of the present disclosure.

FIG. 4 is a block diagram illustrating a semiconductor IC according to a fourth embodiment of the present disclosure.

FIG. 5 is a flowchart illustrating a multimedia processing method being applied to a car navigation system according to an exemplary embodiment of the present disclosure.

FIG. 6 is a flowchart illustrating detailed steps of the step S540 shown in FIG. 5.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

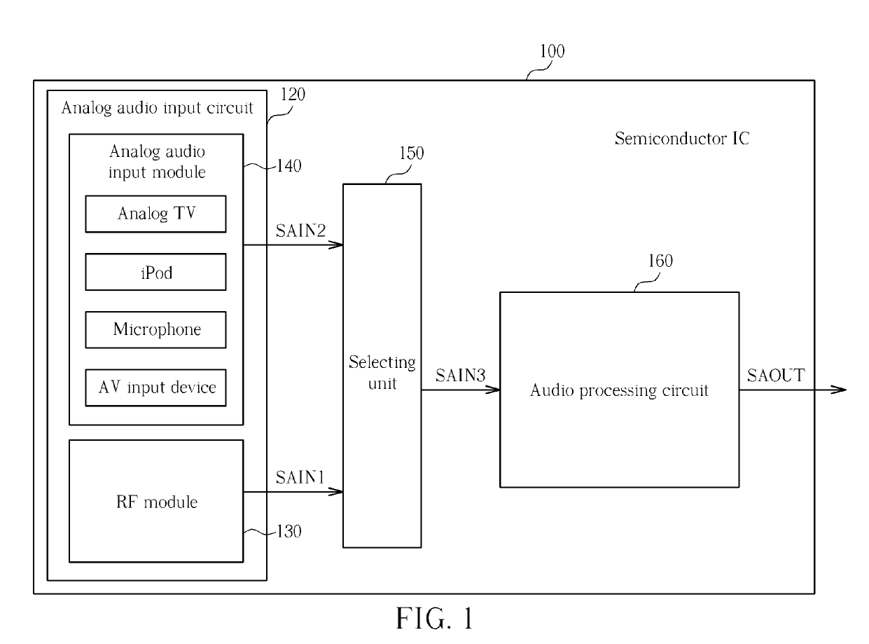

FIG. 1 is a block diagram illustrating a semiconductor integrated circuit (IC) 100 according to a first embodiment of the present disclosure. As shown in FIG. 1, the semiconductor IC 100 includes, but is not limited to an analog audio input circuit 120, a selecting unit 150, and an audio processing circuit 160. The analog audio input circuit 120 includes a radio frequency (RF) module 130 and at least one analog audio input module. For clarity and simplicity, only one analog audio input module 140 is shown in FIG. 1. Please note that all of the elements (including the RF module 130, the analog audio input module 140, the selecting unit 150, and the audio processing circuit 160) are disposed in the same semiconductor IC 100.

In this embodiment, the RF module 130 is arranged to provide a first analog audio input signal SAIN1, wherein the RF module 130 at least includes a frequency module/amplitude modulation (AM/FM) broadcast receiving function. The at least one analog audio input module (e.g., the analog audio input module 140) is arranged to provide at least one second analog audio input signal SAIN2. For example, the analog audio input module 140 may be implemented by an analog television (TV), an iPOD, a microphone, and/or an audio/video (AV) input device. But this is not meant to be a limitation of the present disclosure. For example, an analog audio input device with any type can be adopted for implementing the at least one analog audio input module 140. Moreover, the selecting unit 150 is coupled to the RF module 130 and the at least one analog audio input module 140, and is arranged to output a target analog audio input signal SAIN3 according to the first analog audio input signal SAIN1 and the at least one second analog audio input signal SAIN2. The audio processing circuit 160 is coupled to the selecting unit 150, and is arranged to perform an audio signal process upon the target analog audio signal SAIN3 and accordingly generate an audio output signal SAOUT. Operations and elements of the RF module 130, the selecting unit 150, and the audio processing circuit 160 will be detailed as follows.

In one embodiment, the selecting unit 150 may be implemented by a multiplexer, and thus the multiplexer can select the first analog audio input signal SAIN1 or the at least one second analog audio input signal SAIN2 as the target analog audio input signal SAIN3. In another embodiment, the selecting unit 150 may be implemented by a mixer, and thus the mixer can generate the target analog audio input signal SAIN3 by mixing the first analog audio input signal SAIN1 and the at least one second analog audio input signal SAIN2. Those skilled in the art should readily appreciate that various modifications of achieving the functions of the selecting unit 150 shown in FIG. 1 may be made without departing from the spirit of the present disclosure.

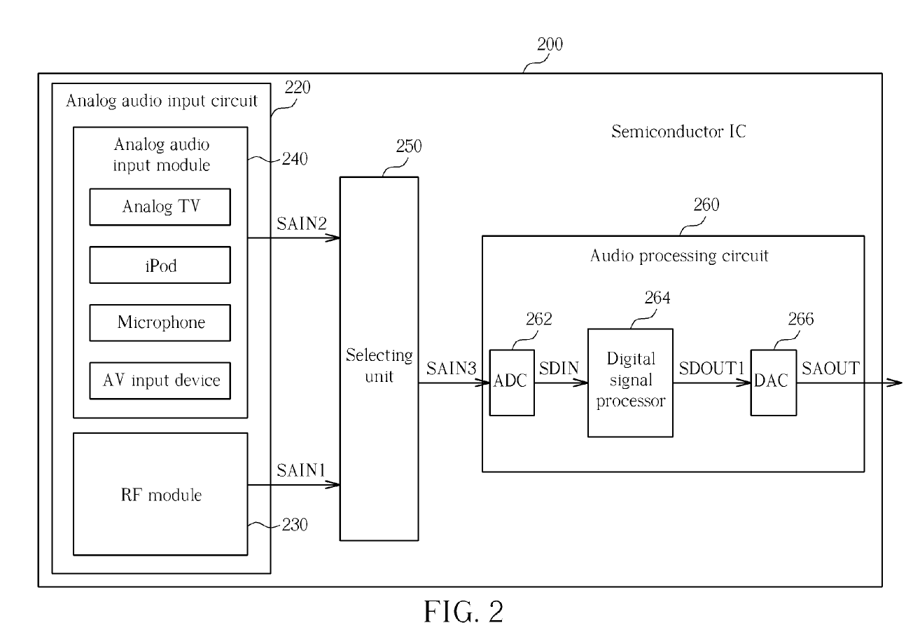

FIG. 2 is a block diagram illustrating a semiconductor IC 200 according to a second embodiment of the present disclosure. As shown in FIG. 2, the semiconductor IC 200 includes, but is not limited to, an analog audio input circuit 220, a selecting unit 250, and an audio processing circuit 260. The analog audio input circuit 220 includes an RF module 230 and at least one analog audio input module. Similarly, only one analog audio input module 240 is shown in FIG. 2 for clarity and simplicity. In this embodiment, the architecture of the semiconductor IC 200 is similar to that of the semiconductor IC 100 shown in FIG. 1, and the major difference therebetween is that the audio processing circuit 260 shown in FIG. 2 includes an analog-to-digital converter (ADC) 262, a digital signal processor 264, and a digital-to-analog converter (DAC) 266. The ADC 262 is coupled to the selecting unit 250, and is arranged to perform an analog-to-digital conversion upon the target analog audio input signal SAIN3 to generate a digital audio input signal SDIN. The digital signal processor 264 is coupled to the analog-to-digital converter 262, and is arranged to perform a digital signal process upon the digital audio input signal SDIN to generate a digital audio output signal SDOUT1. The digital-to-analog converter 266 is coupled to the digital signal processor 264, and is arranged to perform a digital-to-analog conversion upon the digital audio output signal SDOUT1 to generate the audio output signal SAOUT.

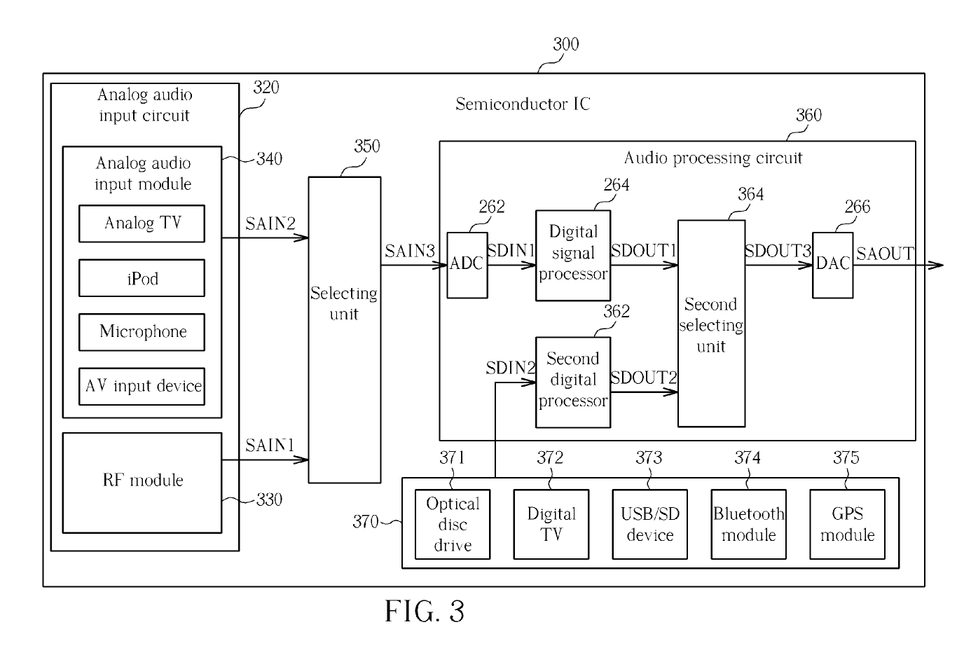

FIG. 3 is a block diagram illustrating a semiconductor IC 300 according to a third embodiment of the present disclosure. As shown in FIG. 3, the semiconductor IC 300 includes, but is not limited to, an analog audio input circuit 320, a selecting unit 350, and an audio processing circuit 360. The analog audio input circuit 320 includes an RF module 330 and at least one analog audio input module. Similarly, only one analog audio input module 340 is shown in FIG. 3 for clarity and simplicity. In this embodiment, the architecture of the semiconductor IC 300 is similar to that of the semiconductor IC 200 shown in FIG. 2, and the major difference therebetween is that the semiconductor IC 300 further includes at least one digital audio input circuit 370, such as an optical disc drive 371, a digital TV 372, a USB/SD device 373, a Bluetooth module 374, and/or a global positioning system (GPS) module 375, for providing a second digital audio input signal SDIN2. Therefore, besides the ADC 262, the digital signal processor 264, and the DAC 266, the audio processing circuit 360 further includes a second digital signal processor 362 and a second selecting unit 364. The second digital signal processor 362 is arranged to perform a digital signal process upon the second digital audio input signal SDIN2 to generate a second digital audio output signal SDOUT2. The second selecting unit 364 is coupled to the digital signal processor 264, the second digital signal processor 362, and the DAC 266, and is arranged to output a resultant digital audio output signal SDOUT3 according to the digital audio output signal SDOUT1 and the second digital audio output signal SDOUT2. After that, the digital-to-analog converter 266 performs the digital-to-analog conversion upon the resultant digital audio output signal SDOUT3 to generate the audio output signal SAOUT.

BY way of example, but not limitation, the second selecting unit 364 may be implemented by a multiplexer or a mixer; however, the present disclosure is not limited to this only. In other embodiments, the second selecting unit 364 can be implemented by a selector with any type.

Please note that, each of the above-mentioned audio signals, such as the analog audio input signal SAIN1/SAIN2/SAIN3, the digital audio input signal SDIN, the digital audio output signal SDOUT1/SDOUT2/SDOUT3, and the audio output signal SAOUT, can be a mono audio signal or a stereo audio signal having a left audio signal (L) and a right audio signal (R). Those skilled in the art should readily appreciate that the proposed multimedia processing apparatus is allowed to support other types of audio signals without departing from the scope of the present disclosure.

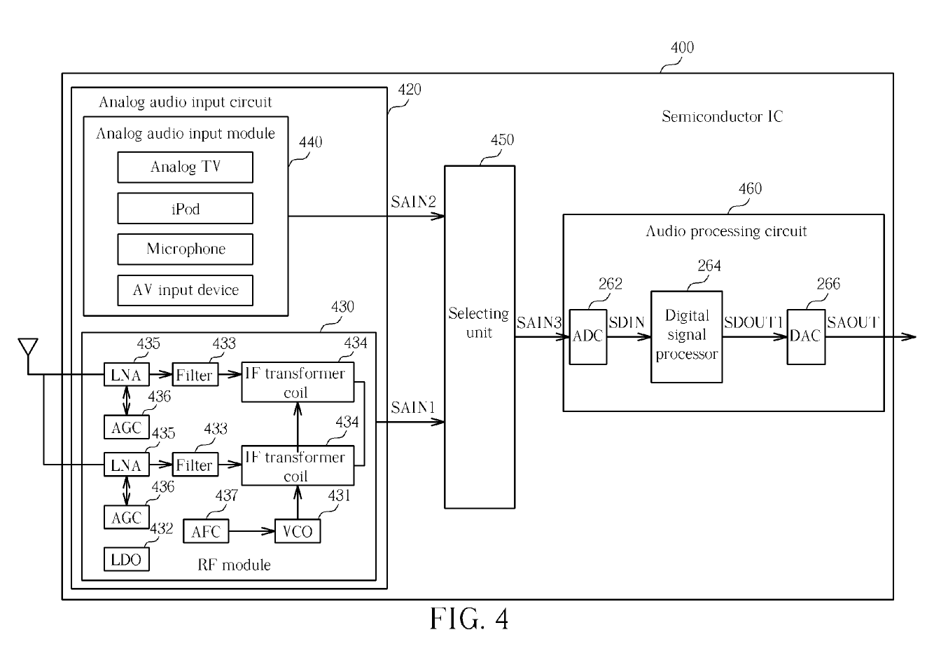

FIG. 4 is a block diagram illustrating a semiconductor IC 400 according to a fourth embodiment of the present disclosure. As shown in FIG. 4, the semiconductor IC 400 includes, but is not limited, an analog audio input circuit 420, a selecting unit 450, and an audio processing circuit 460. The analog audio input circuit 420 includes an RF module 430 and at least one analog audio input module. Similarly, only one analog audio input module 440 is shown in FIG. 4 for clarity and simplicity. In this embodiment, the architecture of the semiconductor IC 400 is similar to that of the semiconductor IC 200 shown in FIG. 2, and the major difference therebetween is that the RF module 430 includes, but is not limited to, a voltage-controlled oscillator (VCO) 431, a low dropout regulator (LDO regulator) 432, a filter 433, an intermediate-frequency (IF) transformer coil 434, a low-noise amplifier (LNA) 435, an automatic gain controller (AGC) 436, and an automatic frequency controller (AFC) 437. Certainly, people skilled in the art will readily appreciate that other designs for implementing the RF module 430 are feasible without departing from the scope of the present disclosure.

Please also note that, the above-mentioned RF module 130/230/330/430 is equipped with a frequency modulation/amplitude modulation (FM/AM) broadcast receiving function. In addition, the semiconductor IC 100/200/300/400 may be implemented by a car navigation chip, and can be integrated in a car navigation system; however, this is not meant to be a limitation of the present disclosure.

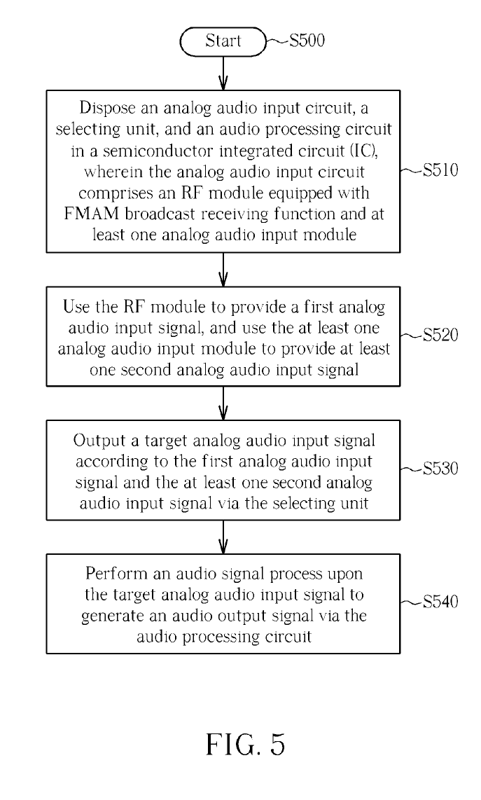

FIG. 5 is a flowchart illustrating a multimedia processing method applied to a car navigation system according to an exemplary embodiment of the present disclosure. Please note that the steps are not required to be executed in the exact order shown in FIG. 5, provided that the result is substantially the same. The generalized multimedia processing method may include the following steps:

Step S500: Start.

Step S510: Dispose an analog audio input circuit, a selecting unit, and an audio processing circuit in a semiconductor integrated circuit (IC), wherein the analog audio input circuit comprises an RF module equipped with FM/AM broadcast receiving function and at least one analog audio input module.

Step S520: Use the RF module to provide a first analog audio input signal, and use the at least one analog audio input module to provide at least one second analog audio input signal.

Step S530: Output a target analog audio input signal according to the first analog audio input signal and the at least one second analog audio input signal via the selecting unit.

Step S540: Perform an audio signal process upon the target analog audio input signal to generate an audio output signal via the audio processing circuit.

As a person skilled in the art can readily understand the details of the steps in FIG. 5 after reading above paragraphs directed to the semiconductor IC 100/200/300/400, further description is omitted here for brevity. The step S520 can be executed by the RF module 130/230/330/430 and the at least one analog audio input module (e.g., 140/240/340/440), the step S530 can be executed by the selecting unit 150/250/350/450, and the step S540 can be executed by the audio processing circuit 160/260/360/460.

Please note that, the above-mentioned flowchart is merely a practicable embodiment of the present disclosure, and in no way should be considered to be limitations of the scope of the present disclosure. The exemplary method can include other intermediate steps, or several steps can be merged into a single step, or the above-mentioned steps can be slightly modified without departing from the spirit of the present disclosure. By way of example, in one embodiment, the selecting unit may be implemented by a multiplexer, and thus the step S530 can be slightly modified as: selecting the first analog audio input signal or the at least one second analog audio input signal as the target analog audio input signal via the multiplexer.

In another embodiment, the selecting unit may be implemented by a mixer, and thus the step S530 can be slightly modified as: mixing the first analog audio input signal and the at least one second analog audio input signal to generate the target analog audio input signal via the mixer. These alternative designs all belong to the scope of the present disclosure.

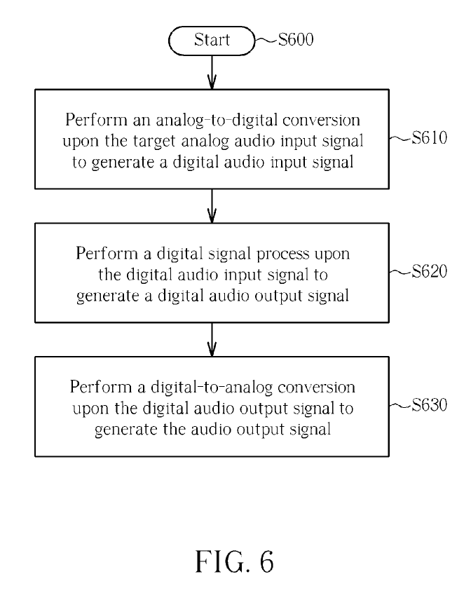

In addition, the method shown in FIG. 5 may include other intermediate steps or several steps can be merged into a single step. Please refer to FIG. 6, which is a flowchart illustrating detailed steps of the step S540 shown in FIG. 5. In this embodiment, the step S540 further includes, but is not limited to, the following steps:

Step S600: Start.

Step S610: Perform an analog-to-digital conversion upon the target analog audio input signal to generate a digital audio input signal.

Step S620: Perform a digital signal process upon the digital audio input signal to generate a digital audio output signal.

Step S630: Perform a digital-to-analog conversion upon the digital audio output signal to generate the audio output signal.

As a person skilled in the art can readily understand the details of the steps in FIG. 6 after reading above paragraphs directed to the semiconductor IC 200/300/400, further description is omitted here for brevity. Be noted that the step S610 can be executed by the ADC 262, the step S620 can be executed by the digital signal processor 264, and the step S630 can be executed by the DAC 266.

The above-mentioned embodiments are presented merely for describing features of the present disclosure, and in no way should be considered to be limitations of the scope of the present disclosure. In summary, the present disclosure provides a multimedia processing apparatus and a related multimedia processing method applied to a car navigation system. As one can see from the figures, the RF module equipped with an RF/AM broadcast receiving function is integrated onto a car navigation chip in the present disclosure. Additionally, the audio processing circuit (including the analog-to-digital converter, the digital signal processor, and the digital-to-analog converter) originally disposed in the car navigation chip is adopted for performing the audio signal process upon the target analog audio input signal. As a result, an extra FM/AM radio receiver equipped with the FM/AM broadcast receiving function can be saved. Therefore, not only can the production cost and the system board area be reduced, but also the circuit architecture of the car navigation chip can be simplified.

Those skilled in the art will readily observe that numerous modifications and alterations of the device and method may be made while retaining the teachings of the disclosure.

1. A semiconductor integrated circuit (IC), comprising:
an analog audio input circuit, comprising:
a radio frequency (RF) module, at least comprising a frequency modulation/amplitude modulation (FM/AM) broadcast receiving function, arranged to provide a first analog audio input signal; and
at least one analog audio input module, arranged to provide at least one second analog audio input signal;
a selecting unit, coupled to the RF module and the at least one analog audio input module, arranged to output a target analog audio input signal according to the first analog audio input signal and the at least one second analog audio input signal; and
an audio processing circuit, coupled to the selecting unit, arranged to perform an audio signal process upon the target analog audio input signal to generate an audio output signal.

2. The semiconductor IC of claim 1, wherein the selecting unit is a multiplexer, and the multiplexer selects the first analog audio input signal or the at least one second analog audio input signal as the target analog audio input signal.

3. The semiconductor IC of claim 1, wherein the selecting unit is a mixer, and the mixer mixes the first analog audio input signal and the at least one second analog audio input signal to generate the target analog audio input signal.

4. The semiconductor IC of claim 1, wherein the RF module comprises a voltage-controlled oscillator (VCO), a low dropout regulator (LDO regulator), a filter, an intermediate-frequency (IF) transformer coil, a low-noise amplifier (LNA), an automatic gain controller (AGC), and an automatic frequency controller (AFC).

5. The semiconductor IC of claim 1, wherein the at least one analog audio input module further comprises an analog TV, an iPOD, a microphone, or an AV input device.

6. The semiconductor IC of claim 1, wherein the semiconductor IC is a car navigation chip.

7. The semiconductor IC of claim 1, wherein the audio processing circuit comprises:
an analog-to-digital converter, coupled to the selecting unit, arranged to perform an analog-to-digital conversion upon the target analog audio input signal to generate a digital audio input signal;
a first digital signal processor, coupled to the analog-to-digital converter, arranged to perform a digital signal process upon the digital audio input signal to generate a first digital audio output signal; and
a digital-to-analog converter, coupled to the first digital signal processor, arranged to perform a digital-to-analog conversion upon the first digital audio output signal to generate the audio output signal.

8. The semiconductor IC of claim 7, further comprising:
a digital audio input circuit, arranged to provide a second digital audio input signal;
wherein the audio processing circuit further comprises:
a second digital signal processor, coupled to the digital audio input circuit, arranged to perform a digital signal process upon the second digital audio input signal to generate a second digital audio output signal;
a second selecting unit, coupled to the first digital signal processor, the second digital signal processor, and the digital-to-analog converter, arranged to output a resultant digital audio output signal according to the first digital audio output signal and the second digital audio output signal.

9. The semiconductor IC of claim 8, wherein the digital audio input circuit comprises an optical disc drive, a digital TV, a USB/SD device, a Bluetooth module, or a global positioning system (GPS) module.

10. A multimedia processing method applied to a car navigation system, comprising:
disposing an analog audio input circuit, a selecting unit, and an audio processing circuit in a semiconductor integrated circuit (IC), wherein the analog audio input circuit comprises an RF module and at least one analog audio input module, and the RF module at least comprises a frequency modulation/amplitude modulation (FM/AM) broadcast receiving function;
using the RF module to provide a first analog audio input signal, and using the at least one analog audio input module to provide at least one second analog audio input signal;
outputting a target analog audio input signal according to the first analog audio input signal and the at least one second analog audio input signal via the selecting unit;
performing an audio signal process upon the target analog audio input signal to generate an audio output signal via the audio processing circuit.

11. The multimedia processing method of claim 10, wherein the selecting unit is a multiplexer; and the step of outputting the target analog audio input signal according to the first analog audio input signal and the at least one second analog audio input signal via the selecting unit comprises:
selecting the first analog audio input signal or the at least one second analog audio input signal as the target analog audio input signal via the multiplexer.

12. The multimedia processing method of claim 10, wherein the selecting unit is a mixer; and the step of outputting the target analog audio input signal according to the first analog audio input signal and the at least one second analog audio input signal via the selecting unit comprises:
mixing the first analog audio input signal and the at least one second analog audio input signal to generate the target analog audio input signal via the mixer.

13. The multimedia processing method of claim 10, wherein the step of performing the audio signal process upon the target analog audio signal to generate the audio output signal via the audio processing circuit comprises:
performing an analog-to-digital conversion upon the target analog audio input signal to generate a digital audio input signal;
performing a digital signal process upon the digital audio input signal to generate a digital audio output signal; and
performing a digital-to-analog conversion upon the digital audio output signal to generate the audio output signal.
